(19) United States
(12) Patent Application Publication
(10) Pub. No.: US 2015/0017798 A1
(43) Pub. Date: Jan. 15, 2015

(54) METHOD OF MANUFACTURING THROUGH-SILICON-VIA

(71) Applicant: United Microelectronics Corp., Hsin-Chu City (TW)

(72) Inventor: Jubao Zhang, Singapore (SG)

(21) Appl. No.: 13/939,182

(22) Filed: Jul. 11, 2013

(51) Int. Cl. H01L 21/768

(52) U.S. Cl. CPC H01L 21/76843; H01L 21/76877; H01L 21/76802
USPC 438/653

(57) ABSTRACT

A method of manufacturing through-silicon-via (TSV) including the steps of sequentially forming a liner layer and a metal layer in a TSV hole, performing a chemical mechanical polishing process to remove the metal layer on the substrate so that the remaining metal layer in the TSV hole becomes a TSV, and forming a cap layer on the substrate without performing a NH₃ treatment.

### BACKGROUND OF THE INVENTION

1. Field of the Invention

The present invention relates generally to a method of manufacturing a through-silicon-via (TSV), and more particularly, to a method of manufacturing a through-silicon-via that can reduce TSV void and bump defect.

2. Description of the Prior Art

In order to improve the performances and the functionality of integrated circuits and to reduce the manufacturing costs of integrated circuit dice, the semiconductor manufacturers have developed three-dimensional multi-chip stack packaging technology to enable vertical integrations of semiconductor device chips. The 3D multi-chip stack packaging technology may employ wafer-level package technology, in which the stacked substrates maybe full wafers typically having multiple chips. The 3D stacked structure can be diced into individual units after bonding, each unit having two or more chips vertically bonded together. Typically, a semiconductor chip includes several layers of integrated circuitry (e.g., processors, programmable devices, memory devices, etc.) built on a semiconductor substrate. Atop layer of the bonded stack may be connected to a bottom layer of the stack utilizing through substrate interconnects, or is commonly known as through-silicon- vias (TSVs).

The through-silicon-vias are usually made by forming vertical through holes in semiconductor wafers and filling the through holes with insulating materials and metallic materials. Copper electrodes with relatively high hardness are then formed on the through-silicon-vias to provide vertical interconnection between semiconductor wafers/chips to form the 3D multi -chip stack structures. Copper is preferred as an interconnect material for TSVs due to its high conductivity and lower specific resistance, which may reduce the interconnect resistance to achieve faster operation of a device.

However, conventional Cu TSV structures may suffer serious Cu void and bump issues. The presence of hollow voids in a Cu interconnect in a multiple-layered interconnect may increase the resistance and deteriorate the reliability of the devices, and the Cu bumps protruding from the surface of the TSV may lower the flatness of the substrate and affect the following manufacturing processes. Both of these two issues may lead to a problem of reduced production yield of semiconductor devices/chips. Thus, how to manufacture a Cu TSV structure completely free of void and bump defects is an important topic for those of skilled in the art to continuously improve the relevant processes and provide better solutions.

### SUMMARY OF THE INVENTION

It is therefore one objectives of the present invention to provide a method of manufacturing a through-silicon-via structure which is free of void and bump defects.

One object of the present invention is to provide a method of manufacturing through-silicon-via comprising the steps of: providing a substrate; forming a TSV hole in the substrate; conformally forming a liner layer on the substrate and the TSV hole; performing a chemical mechanical polishing process to remove the metal layer on the substrate, so that the remaining metal layer in the TSV hole becomes a through-silicon-via; and forming a cap layer on the substrate and the through-silicon-via without performing an NH₃ treatment.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute apart of this specification. The drawings illustrate some of the embodiments and, together with the description, serve to explain their principles. In the drawings:

FIGS. 1-6 are cross-sectional views schematically depicting a process flow for manufacturing a through-silicon-via in accordance with one embodiment of present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following detailed description of the present invention, reference is made to the accompanying drawings which form a part hereof and is shown by way of illustration and specific embodiments in which the invention may be practiced. These embodiments are described in sufficient details to enable those skilled in the art to practice the invention. Other embodiments may be utilized and structural, logical, and electrical changes may be made without departing from the scope of the present invention. The following detailed description, therefore, is not to be taken in a limiting sense, and the scope of the present invention is defined by the appended claims.

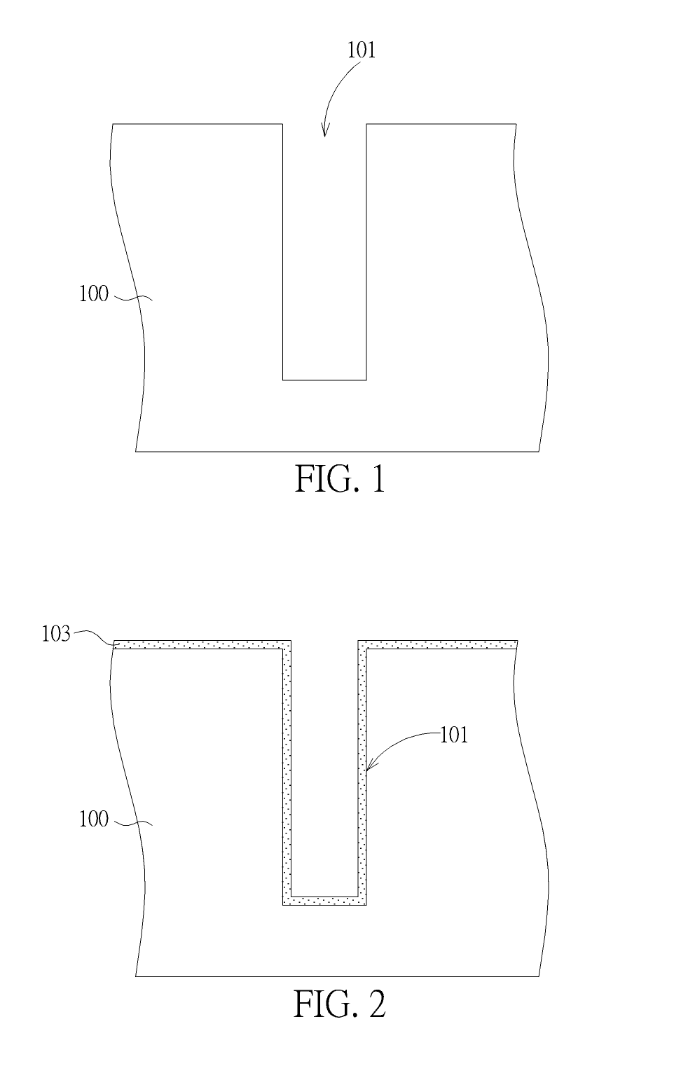

Please refer to FIGS. 1-6, which are cross-sectional views schematically depicting a process flow for manufacturing a through-silicon-via (TSV) in accordance with one embodiment of the present invention. First, as shown in FIG. 1, a semiconductor substrate 100 is provided to serve as a base for forming devices, components, or TSV holes. The substrate 100 is preferably composed of a silicon containing material. Silicon containing materials include, but are not limited to, Si, single crystal Si, polycrystalline Si, SiGe, single crystal silicon germanium, polycrystalline silicon germanium, or silicon doped with carbon, amorphous Si and combinations and multi-layered materials thereof. The semiconductor substrate 100 may also be composed of other semiconductor materials, such as germanium, and compound semiconductor substrates, such as type III/V semiconductor substrates, e.g., GaAs. Although the semiconductor substrate 100 is depicted as a bulk semiconductor substrate, the arrangement of a semiconductor on an insulator substrate, such as silicon-on-insulator (SOI) substrates, are also suitable for semiconductor substrate 100.

An etching process is performed on the semiconductor substrate 100 to form a TSV hole 101. The etching process may include first forming a mask (not shown) on the substrate 100 to define the pattern of the TSV hole 101. This mask is composed of an etchant resistant material, such as silicon nitride (SiN), which may be formed on the substrate 100 by using chemical vapor deposition (CVD) process, plasma-enhanced chemical vapor deposition (PECVD) process, or physical vapor deposition (PVD) process. The TSV hole 101 is then etched into the substrate 100 through the mask, typically with a width from 10 to 100 micron (μm) and a depth from 50 to 100 μm. The TSV hole 101 may or may not extend through the substrate 100 depending on the different stage of TSV fabrication, such as the via-first stage, via-middle stage, or the via-last stage. In this embodiment, the TSV hole 101 maybe formed before or after the front-end-of-the-line (FEOL) processing (device creation) on the substrate 100, such as a standard metal-oxide semiconductor (MOS) transistor fabrication process performed to form at least one MOS transistor or other semiconductor devices on the semiconductor substrate 100. These MOS transistors could be typical transistor structures including gates, spacers, lightly doped drains, source/drain regions and/or salicides.

After the TSV hole 101 is formed, please refer to FIG. 2, a liner layer 103 is conformally formed on the surface of the substrate 100 and the TSV hole 101. The liner layer 103 serves as an electrical isolation between the TSV and the semiconductor substrate 100. In this embodiment, the liner layer 103 may be composed of insulating materials such as oxides or nitrides, with a thickness about 1 μm or less. The liner layer 103 may be a single layer or multi-layer structure, such as a tri-layer composed of a plasma-enhanced oxide layer/a liner layer/a plasma-enhanced oxide layer. The liner layer 103 may be formed through several adequate processes, for example, a low temperature (about 430° C.) sub-atmospheric chemical vapor deposition (SACVD) process, low pressure chemical vapor deposition (LPCVD) process or a high temperature (above 1000° C.) furnace oxidation process. A baking process maybe optionally performed after the liner layer 103 is formed to remove water vapor remained on the liner layer 103, so that the materials to be deposited or formed on the liner layer 103 in following process could adhere thereon more effectively.

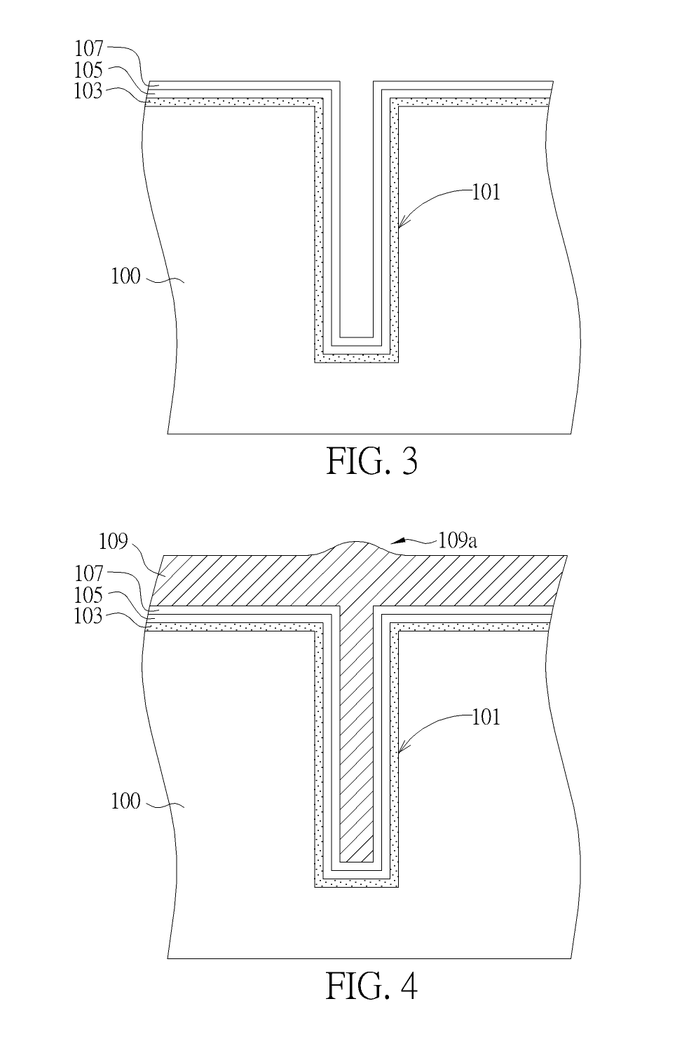

After the liner layer 103 is formed, please refer to FIG. 3, a barrier layer 105 and a seed layer 107 are conformally formed on the liner layer 103. The barrier layer 105 is used to prevent larger conductive portion in the TSV (normally copper (Cu)) from migrating into the semiconductor substrate 100 which would lead to electrical leakage issues or pollute the device. The barrier layer 105 may be preferably selected from a group consisting of Ta, TaN, Ti, TiN, W and WN, with a thickness normally on the order of a few thousand Angstroms (A) or less. Additionally, the seed layer 107 is used to facilitate the adhesion of the metal ions (ex. copper ions) onto the liner layer 105 for the following electroplating process. The seed layer 107 is preferably made of copper and may comprise a substantial portion of the TSV to be formed with a thickness of a few thousand Angstroms. In the present invention, both of the barrier layer 105 and the seed layer 107 may be formed by using sputtering process, atomic layer deposition (ALD) process, or CVD process.

After the barrier layer 105 and the seed layer 107 are formed, please refer to FIG. 4, an electro-chemical plating (ECP) process is performed to form a metal layer 109 composed of, but is not limited to, copper on the surface of seed layer 107. The ECP process is continuously performed until the entire TSV hole 101 is filled up with the metal layer 109. It should be noted that the metal layer 109 could also be composed of conductive materials other than copper, and the material of the seed layer 107 could be adjusted according to the material of the metal layer 109.

Optionally, an anneal process could be carried out thereafter to improve the stability of the formed metal layer 109. In this embodiment, the anneal process preferably includes a furnace anneal process, in which the process time is substantially greater than 10 minutes at a temperature larger than 400° C., preferably at 420° C. with a duration of 30 minutes. When the filler metal filled in the TSV hole 101 is constrained by the sidewalls of the TSV hole 101 under a high-temperature environment with its top surface exposed, an upwardly-diffusing movement of the filler metal occurs to relieve the resulting compressive stress, thereby forming a stress-induced metal protrusion (commonly referred as a hillock structure) 109a emerging from the metal layer 109 above the TSV hole 101.

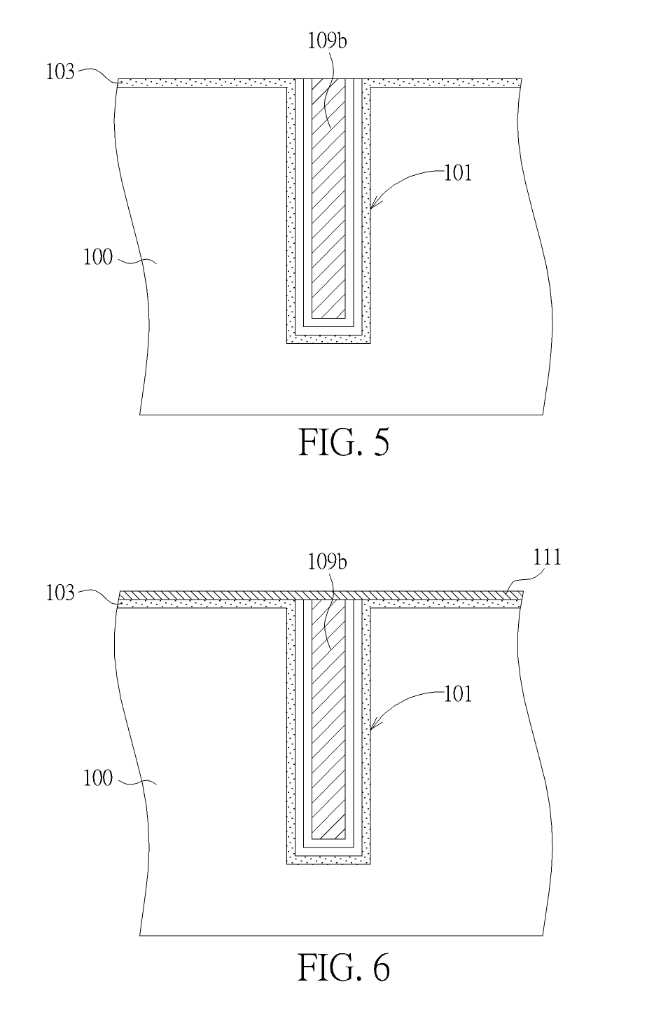

In the following process, please refer to FIG. 5, a planarization process, such as a chemical mechanical polishing (CMP) process, is conducted on the substrate 100 by using the liner layer 103 as a stop layer. A portion of the metal layer 109, the seed layer 107, the barrier layer 105 and the liner layer 103 on the surface of the substrate 100 are removed after the CMP process, so that the remaining metal layer 109 filled within the TSV hole 101 is even with the liner layer 103 and becomes a TSV 109b. The thickness of the liner layer 103 on the substrate may slight reduce, for example, from 11000 Angstroms to 9600 Angstroms due to the wearing of the polishing process.

In next step, as shown in FIG. 6, a post-TSV masking cap layer 111 is then deposited over the exposed end of the TSV 109b (and may include the other end if existing) to prevent the formed TSV 109b from being oxidized, contaminated or being damaged before conducting the subsequent processes. The cap layer 111 is preferably a SiN layer or a SiON, which may be formed by using CVD, PECVD, or PVD processes at a process temperature about 400° C. with a duration of 6 minutes. In other embodiments, the material of the cap layer 111 may be the etchant resistant material other than SiN. At this stage, a process of manufacturing a TSV structure is adequately completed. The cap layer 111 maybe removed thereafter by using reactive-ion etch (RIE) process once the TSV 109b is ready to establish the electrical connection with other structures, such as a contact pad or a I/O pad, in a back-end-of-the-line (BEOL) process for the semiconductor chip fabrication.

One essential feature of the present invention is that the forming step of the cap layer 111 doesn't include a common NH₃ treatment at a process temperature about 400° C. with a duration of 10 seconds. It is proved that the high-temperature environment of the NH₃ treatment may induce an outgassing behavior of the elements such as S, Cl, C in the TSV 109b. Void defects may be formed in TSV 109b because of this outgassing behavior. Accordingly, by skipping the regular NH₃ treatment, the method of the present invention may manufacture a through-silicon-via free from the void defects. Furthermore, the optimization of the annealing process for the metal layer, preferably at 420° C. with a duration of 30 minutes, may effectively reduce the TSV bump defect.

Additionally, a back-side thinning process (ex. another CMP process or a plasma etching process) may be performed on the other side of the substrate 100 until the formed TSV 109b is exposed on the other side and extends all the way through the semiconductor substrate 100.

The aforementioned embodiment could also be applied to different stages of the TSV fabrication, such as during a via-first stage where a TSV filled with oxide is first formed before the formation of a CMOS transistor and the TSV is formed on the back of the wafer thereafter, or during a via-last stage where a TSV is formed after the fabrication of metal interconnects are completed. All of these modifications are all within the scope of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of manufacturing through-silicon-via, comprising the steps of:
providing a substrate;
forming a TSV hole in said substrate;
conformally forming a liner layer on said substrate and said TSV hole;
forming a metal layer on said liner layer;
performing a chemical mechanical polishing process to remove said metal layer on said substrate, so that the remaining said metal layer in said TSV hole becomes a through-silicon-via; and
forming a cap layer on said substrate and said through-silicon-via without performing a NH₃ treatment.

2. A method of manufacturing through-silicon-via according to claim 1, further comprising conformally forming a barrier layer on said liner layer.

3. A method of manufacturing through-silicon-via according to claim 1, further comprising conformally forming a seed layer on said barrier layer.

4. A method of manufacturing through-silicon-via according to claim 1, further comprising performing an annealing process to said metal layer before performing said chemical mechanical polishing process.

5. A method of manufacturing through-silicon-via according to claim 1, wherein said anneal process is performed at a temperature larger than 400° C. with a duration of 30 minutes.

6. A method of manufacturing through-silicon-via according to claim 1, wherein said liner layer is formed by using a sub-atmospheric chemical vapor deposition process, a low pressure chemical vapor deposition process, or a furnace oxidation process.

7. A method of manufacturing through-silicon-via according to claim 1, wherein said barrier layer is formed by using a sputtering process, an atomic layer deposition process, or a chemical vapor deposition process.

8. A method of manufacturing through-silicon-via according to claim 1, wherein said metal layer is formed by using an electro-chemical plating process.

9. A method of manufacturing through-silicon-via according to claim 1, wherein said cap layer is formed by using a chemical vapor deposition process, a plasma-enhanced chemical vapor deposition process, or a physical vapor deposition process.
